(19) United States
(12) Patent Application Publication
(10) Pub. No.: US 2026/0205330 A1
(43) Pub. Date: Jul. 16, 2026

(54) SELECTION SUMMING LATCH CIRCUIT FOR A DECISION FEEDBACK EQUALIZER

(71) Applicant: NOREL SYSTEMS LIMITED, Tianjin (CN)

(72) Inventors: Xuedong LIANG, Tianjin (CN); Ting WU, Tianjin (CN)

(21) Appl. No.: 19/565,662

(22) Filed: Mar. 13, 2026

Related U.S. Application Data
(63) Continuation of application No. PCT/CN2024/118942, filed on Sep. 14, 2024.

(30) Foreign Application Priority Data
Sep. 14, 2023 (CN) 202311184659.2

(51) Int. Cl. H04L 25/03; H03K 3/037

(52) U.S. Cl. CPC H04L 25/03267; H03K 3/037

(57) ABSTRACT

A selection summing latch circuit for a decision feedback equalizer includes a selection summing unit, a latch amplifier, a sampler and a resetter. When a sampling clock is at a high level, the selection summing unit is configured to selectively select a positive reference voltage or a negative reference voltage to sum with an input signal according to the logic levels of a positive selection signal terminal and a negative selection signal terminal to obtain a summation result, the latch amplifier is configured to latch and amplify the summation result and output an output result to a positive output signal terminal and a negative output signal terminal, and the sampler is configured to sample the selection summing unit. The resetter is configured to reset the positive output signal terminal and the negative output signal terminal when the sampling clock is at a low level.

### CROSS-REFERENCE TO RELATED APPLICATION

This application is a continuation application of International Patent Application No. PCT/CN 2024/118942, filed on Sep. 14, 2024, which itself claims priority to and benefit of Chinese Patent Application No. 202311184659.2, filed on Sep. 14, 2023 in the State Intellectual Property Office of P. R. China. The disclosure of each of the above applications is incorporated herein by reference in its entirety.

### TECHNICAL FIELD

The present invention relates to the technical field of electronic signal processing circuits, and in particular, to a selection summing latch circuit for a decision feedback equalizer.

### BACKGROUND ART

Decision feedback equalization technology can be used to improve the quality of signal reception for accurate data receiving. As shown in FIG. 1, in the typical application of a decision feedback equalizer at present, the main functional part of the decision feedback equalizer is generally realized by the cascade connection of two summing units, two latches and one selector. An input signal from an input signal interface 11 is summed with a positive reference voltage from a positive reference voltage interface 12 in the first summing unit, and the input signal from the input signal interface 11 is summed with a negative reference voltage from a negative reference voltage interface 13 in the second summing unit.

The summation results are then sent to the two latches through a first summation result interface 37 and a second summation result interface 38 respectively for sampling by a sampling clock 15. The sampling results are sent to two input ends of the selector through a first sampling result interface 39 and a second sampling result interface 40 respectively.

The selector is provided with two selection signals, namely a positive selection signal terminal 21 and a negative selection signal terminal 22, where the logic levels of the positive selection signal terminal 21 and the negative selection signal terminal 22 are opposite. The selector selectively selects the input signal of the first sampling result interface 39 or the input signal of the second sampling result interface 40 according to the positive selection signal terminal 21 and the negative selection signal terminal 22. The selector includes two output signals, which are output to a positive output signal terminal 19 and a negative output signal terminal 20 respectively, and the logic levels of the positive output signal terminal 19 and the negative output signal terminal 20 are opposite.

Due to the large number of series stages of the decision feedback equalizer circuit, the time delay from input to output is relatively large, which limits its operating speed and thus affects the operating frequency of the decision feedback equalizer. In addition, the large number of circuit modules leads to relatively high overall power consumption of the circuit.

### SUMMARY

To solve the problems in the prior art that the decision feedback equalizer circuit has a large number of series stages, a large time delay from input to output, which limits its operating speed and affects its operating frequency, and the overall circuit has high power consumption, an objective of the present invention is to provide a selection summing latch circuit for a decision feedback equalizer. The selection summing latch circuit comprises a selection summing unit, a latch amplifier, a sampler and a resetter;

The selection summing unit is configured to selectively select a positive reference voltage or a negative reference voltage to sum with an input signal according to the logic levels of a positive selection signal terminal and a negative selection signal terminal to obtain a summation result when a sampling clock is at a high level;

The latch amplifier is configured to latch and amplify the summation result and output an output result to a positive output signal terminal and a negative output signal terminal when the sampling clock is at a high level;

The sampler is configured to sample the selection summing unit when the sampling clock is at a high level;

The resetter is configured to reset the positive output signal terminal and the negative output signal terminal when the sampling clock is at a low level.

Preferably, the selection summing unit comprises a first NMOS transistor, a second NMOS transistor, a third NMOS transistor, a fourth NMOS transistor and a fifth NMOS transistor;

wherein the second NMOS transistor and the fourth NMOS transistor are connected in series to form a first branch, and the third NMOS transistor and the fifth NMOS transistor are connected in series to form a second branch;

the first NMOS transistor is connected in parallel with the first branch and the second branch respectively.

Preferably, a gate of the first NMOS transistor is connected to an input signal interface; a gate of the second NMOS transistor is connected to a positive reference voltage interface; a gate of the third NMOS transistor is connected to a negative reference voltage interface; a gate of the fourth NMOS transistor is connected to the positive selection signal terminal; a gate of the fifth NMOS transistor is connected to the negative selection signal terminal;

wherein the logic levels of the positive selection signal terminal and the negative selection signal terminal are opposite.

Preferably, a drain of the first NMOS transistor, a drain of the second NMOS transistor and a drain of the third NMOS transistor are connected to one another and to a summation result interface;

a source of the first NMOS transistor, a source of the fourth NMOS transistor and a source of the fifth NMOS transistor are connected to one another and to a summation source interface;

a source of the second NMOS transistor is connected to a drain of the fourth NMOS transistor; a source of the third NMOS transistor is connected to a drain of the fifth NMOS transistor.

Preferably, a drain of the first NMOS transistor, a drain of the fourth NMOS transistor and a drain of the fifth NMOS transistor are connected to one another and to a summation result interface;

a source of the first NMOS transistor, a source of the second NMOS transistor and a source of the third NMOS transistor are connected to one another and to a summation source interface;

a drain of the second NMOS transistor is connected to a source of the fourth NMOS transistor; a drain of the third NMOS transistor is connected to a source of the fifth NMOS transistor.

Preferably, the sampler is connected to the selection summing unit through the summation source interface;

the sampler comprises one or more first sampling MOS transistors, and a gate of each first sampling MOS transistor is connected to the sampling clock;

when the sampling clock is at a high level, the first sampling MOS transistor samples the selection summing unit through the summation source interface.

Preferably, a drain of the first sampling MOS transistor is connected to the summation source interface, and a source of the first sampling MOS transistor is connected to a ground terminal VSS.

Preferably, a source of the first sampling MOS transistor is connected to the summation source interface, and a drain of the first sampling MOS transistor is connected to the ground terminal VSS.

Preferably, the latch amplifier is connected to the selection summing unit through the summation result interface;

the latch amplifier comprises a first latch MOS transistor, a second latch MOS transistor, a third latch MOS transistor, a fourth latch MOS transistor and a second sampling MOS transistor;

the first latch MOS transistor and the third latch MOS transistor are connected in series to form a first latch branch, and the second sampling MOS transistor, the second latch MOS transistor and the fourth latch MOS transistor are connected in series to form a second latch branch;

the first latch branch and the second latch branch are connected in parallel, a gate of the second sampling MOS transistor is connected to the sampling clock, and the third latch MOS transistor is connected to the summation result interface;

the first latch branch is connected to the positive output signal terminal and the negative output signal terminal;

the second latch branch is connected to the positive output signal terminal and the negative output signal terminal.

Preferably, when the sampling clock is at a high level, the second sampling MOS transistor is turned on, the first latch MOS transistor, the second latch MOS transistor, the third latch MOS transistor and the fourth latch MOS transistor form a positive feedback loop, latch and amplify the summation result through the summation result interface, and output the output result to the positive output signal terminal and the negative output signal terminal;

when the sampling clock is at a low level, the second sampling MOS transistor, the second latch MOS transistor and the fourth latch MOS transistor are all turned off.

Preferably, a source of the second sampling MOS transistor is connected to the ground terminal VSS; a drain of the second sampling MOS transistor is connected to a source of the fourth latch MOS transistor; a drain of the fourth latch MOS transistor is connected to a drain of the second latch MOS transistor;

a source of the third latch MOS transistor is connected to the summation result interface; a drain of the third latch MOS transistor is connected to a drain of the first latch MOS transistor;

a source of the second latch MOS transistor and a source of the first latch MOS transistor are connected to a power supply VDD.

Preferably, a drain of the second sampling MOS transistor is connected to the ground terminal VSS; a source of the second sampling MOS transistor is connected to a drain of the fourth latch MOS transistor; a source of the fourth latch MOS transistor is connected to a source of the second latch MOS transistor;

a drain of the third latch MOS transistor is connected to the summation result interface; a source of the third latch MOS transistor is connected to a source of the first latch MOS transistor;

a drain of the second latch MOS transistor and a drain of the first latch MOS transistor are connected to the power supply VDD.

Preferably, the resetter comprises a first reset MOS transistor, a second reset MOS transistor and a third reset MOS transistor;

a gate of the first reset MOS transistor, a gate of the second reset MOS transistor and a gate of the third reset MOS transistor are connected to the sampling clock respectively;

the first reset MOS transistor and the second reset MOS transistor are connected in parallel, the positive output signal terminal is connected to the first reset MOS transistor, the negative output signal terminal is connected to the second reset MOS transistor, and the first reset MOS transistor and the second reset MOS transistor are both connected to the power supply VDD;

the third reset MOS transistor is connected between the positive output signal terminal and the negative output signal terminal.

Preferably, when the sampling clock is at a low level, the first reset MOS transistor, the second reset MOS transistor and the third reset MOS transistor are all turned on to reset the positive output signal terminal and the negative output signal terminal;

when the sampling clock is at a high level, the first reset MOS transistor, the second reset MOS transistor and the third reset MOS transistor are all turned off.

Preferably, a drain of the first reset MOS transistor is connected to the positive output signal terminal, and a source of the third reset MOS transistor is connected to the positive output signal terminal;

a drain of the second reset MOS transistor is connected to the negative output signal terminal, and a drain of the third reset MOS transistor is connected to the negative output signal terminal;

a source of the first reset MOS transistor and a source of the second reset MOS transistor are connected to the power supply VDD.

Preferably, a source of the first reset MOS transistor is connected to the positive output signal terminal, and a drain of the third reset MOS transistor is connected to the positive output signal terminal;

a source of the second reset MOS transistor is connected to the negative output signal terminal, and a source of the third reset MOS transistor is connected to the negative output signal terminal;

a drain of the first reset MOS transistor and a drain of the second reset MOS transistor are connected to the power supply VDD.

Another objective of the present invention is to provide a decision feedback equalizer, which comprises a latch and the above-mentioned selection summing latch circuit provided by the present invention.

Preferably, the positive output signal terminal and the negative output signal terminal of the selection summing latch circuit are connected to the latch;

an output end of the latch is connected to the positive selection signal terminal and the negative selection signal terminal of the selection summing latch circuit;

the latch is provided with a latch clock, and the latch clock and the sampling clock are inverse phase signals to each other.

The selection summing latch circuit and the decision feedback equalizer for a decision feedback equalizer provided by the present invention reduce the time delay and power consumption of the selector, the summing unit and the sampler in the decision feedback equalizer, and improve the performance of the decision feedback equalizer.

The selection summing latch circuit and the decision feedback equalizer for a decision feedback equalizer provided by the present invention integrate the summation function, selection function, sampling function and latching function used in the decision feedback equalizer into the selection summing latch circuit, thereby reducing the overall power consumption, lowering the overall time delay and improving the circuit performance.

### BRIEF DESCRIPTION OF DRAWINGS

To explain the specific embodiments of the present invention or the technical solutions in the prior art more clearly, the drawings required for the description of the specific embodiments or the prior art will be briefly introduced below. Obviously, the drawings in the following description are some embodiments of the present invention, and those skilled in the art can obtain other drawings according to these drawings without creative work.

FIG. 1 schematically shows a connection block diagram of a summing unit, a latch and a selector used in a decision feedback equalizer in the prior art.

FIG. 2 shows an overall block diagram of a selection summing latch circuit for a decision feedback equalizer according to the present invention.

FIG. 3 shows a circuit diagram of a selection summing unit according to the present invention.

FIG. 4 shows a circuit diagram of a sampler according to the present invention.

FIG. 5 shows a circuit diagram of a latch amplifier according to the present invention.

FIG. 6 shows a circuit diagram of a resetter according to the present invention.

FIG. 7 shows an overall block diagram of a decision feedback equalizer according to the present invention.

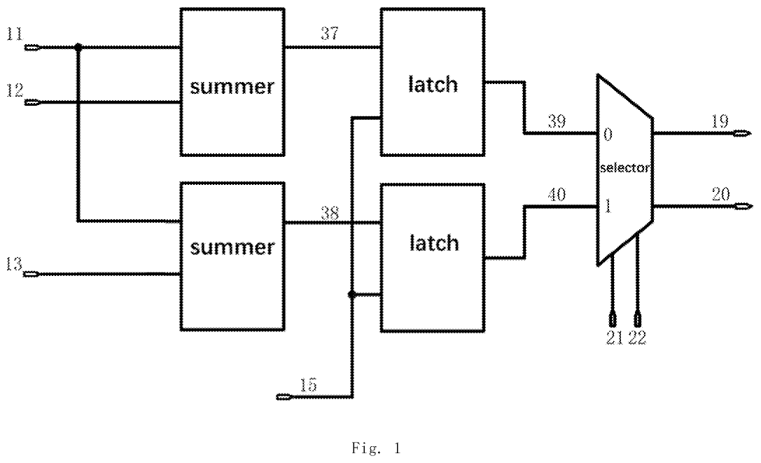

The reference signs in the drawings have the following meanings:
100, selection summing latch circuit; 101, selection summing unit; 102, latch amplifier; 103, sampler; 104, resetter; 201, latch;
11, input signal interface; 12, positive reference voltage interface; 13, negative reference voltage interface; 15, sampling clock; 16, summation source interface; 17, summation result interface; 19, positive output signal terminal; 20, negative output signal terminal; 21, positive selection signal terminal; 22, negative selection signal terminal; 23, latch clock; 37, first summation result interface; 38, second summation result interface; 39, first sampling result interface; 40, second sampling result interface;
M1, first NMOS transistor; M2, second NMOS transistor; M3, third NMOS transistor; M4, fourth NMOS transistor; M5, fifth NMOS transistor;
M31, first sampling MOS transistor;
M41, first latch MOS transistor; M42, second latch MOS transistor; M43, third latch MOS transistor; M44, fourth latch MOS transistor; M45, second sampling MOS transistor;
M51, first reset MOS transistor; M52, second reset MOS transistor; M53, third reset MOS transistor.

### DETAILED DESCRIPTION OF EMBODIMENTS

To make the above and other features and advantages of the present invention clearer, the present invention will be further described below with reference to the accompanying drawings. It should be understood that the specific embodiments provided herein are for the purpose of explaining to those skilled in the art, and are merely exemplary and not restrictive.

As shown in FIG. 2, according to an embodiment of the present invention, a selection summing latch circuit 100 for a decision feedback equalizer is provided. The selection summing latch circuit 100 comprises a selection summing unit 101, a latch amplifier 102, a sampler 103 and a resetter 104.

The selection summing unit 101 is connected to the latch amplifier 102 and the sampler 103, and the sampler 103 is connected to the resetter 104. The latch amplifier 102, the sampler 103 and the resetter 104 are respectively connected to a sampling clock 15.

The selection summing unit 101 is connected to an input signal interface 11, a positive reference voltage interface 12, a negative reference voltage interface 13, a positive selection signal terminal 21 and a negative selection signal terminal 22.

An input signal is input to the selection summing unit 101 through the input signal interface 11, a positive reference voltage is input to the selection summing unit 101 through the positive reference voltage interface 12, a negative reference voltage is input to the selection summing unit 101 through the negative reference voltage interface 13, and the positive selection signal terminal 21 and the negative selection signal terminal 22 provide logic levels for the selection summing unit 101.

The selection summing unit 101 is configured to selectively select the positive reference voltage input from the positive reference voltage interface 12 or the negative reference voltage input from the negative reference voltage interface 13 to sum with the input signal input from the input signal interface 11 to obtain a summation result when the sampling clock 15 is at a high level.

The logic levels of the positive selection signal terminal 21 and the negative selection signal terminal 22 are opposite. When the positive selection signal terminal 21 is at a high level and the negative selection signal terminal 22 is at a low level, the positive reference voltage input from the positive reference voltage interface 12 is selected to sum with the input signal input from the input signal interface 11 in the selection summing unit 101 to obtain a summation result.

When the positive selection signal terminal 21 is at a low level and the negative selection signal terminal 22 is at a high level, the negative reference voltage input from the negative reference voltage interface 13 is selected to sum with the input signal input from the input signal interface 11 in the selection summing unit 101 to obtain a summation result.

The sampler 103 is connected to a ground terminal VSS, and the sampler 103 is connected to the selection summing unit 101 through a summation source interface 16. The latch amplifier 102 is connected to a power supply VDD, and the latch amplifier 102 is connected to the selection summing unit 101 through a summation result interface 17.

The latch amplifier 102 comprises a positive output signal terminal 19 and a negative output signal terminal 20, and the positive output signal terminal 19 and the negative output signal terminal 20 of the latch amplifier 102 are connected to the resetter 104.

The sampler 103 is configured to sample the selection summing unit 101 through the summation source interface 16 when the sampling clock 15 is at a high level.

The latch amplifier 102 is configured to latch and amplify the summation result of the selection summing unit 101 through the summation result interface 17 and output an output result to the positive output signal terminal 19 and the negative output signal terminal 20 when the sampling clock 15 is at a high level.

The resetter 104 is configured to reset the positive output signal terminal 19 and the negative output signal terminal 20 when the sampling clock 15 is at a low level.

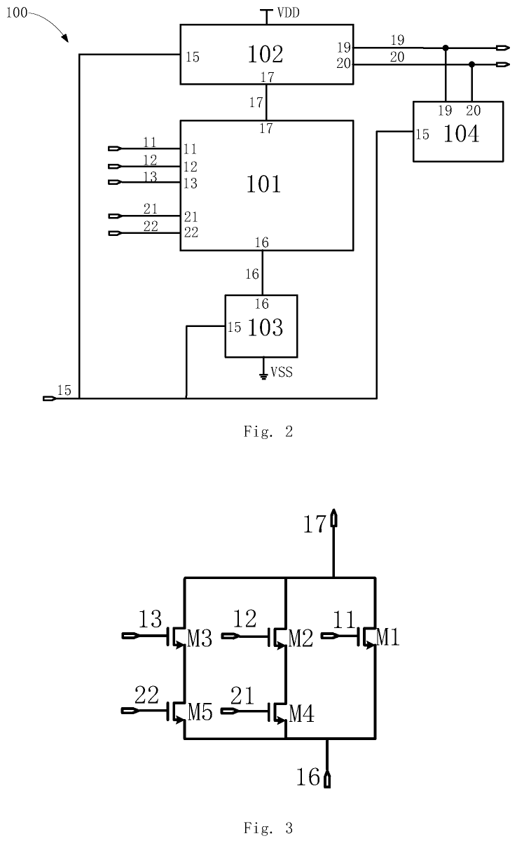

As shown in FIG. 3, according to an embodiment of the present invention, the selection summing unit 101 comprises a first NMOS transistor M1, a second NMOS transistor M2, a third NMOS transistor M3, a fourth NMOS transistor M4 and a fifth NMOS transistor M5.

The second NMOS transistor M2 and the fourth NMOS transistor M4 are connected in series to form a first branch, and the third NMOS transistor M3 and the fifth NMOS transistor M5 are connected in series to form a second branch. The first NMOS transistor M1 is connected in parallel with the first branch and the second branch respectively.

A gate of the first NMOS transistor M1 is connected to the input signal interface 11; a gate of the second NMOS transistor M2 is connected to the positive reference voltage interface 12; a gate of the third NMOS transistor M3 is connected to the negative reference voltage interface 13; a gate of the fourth NMOS transistor M4 is connected to the positive selection signal terminal 21; a gate of the fifth NMOS transistor M5 is connected to the negative selection signal terminal 22.

The logic levels of the positive selection signal terminal 21 and the negative selection signal terminal 22 are opposite. When the positive selection signal terminal 21 is at a high level and the negative selection signal terminal 22 is at a low level, the fourth NMOS transistor M4 is turned on and the fifth NMOS transistor M5 is turned off, and the first branch (the second NMOS transistor M2 and the fourth NMOS transistor M4) is gated on through the fourth NMOS transistor M4. The positive reference voltage input from the positive reference voltage interface 12 is selected to be connected in parallel with the input signal input from the input signal interface 11 for summation in the selection summing unit 101, and the summation result is output to the latch amplifier 102 through the summation result interface 17.

When the positive selection signal terminal 21 is at a low level and the negative selection signal terminal 22 is at a high level, the fourth NMOS transistor M4 is turned off and the fifth NMOS transistor M5 is turned on, and the second branch (the third NMOS transistor M3 and the fifth NMOS transistor M5) is gated on through the fifth NMOS transistor M5. The negative reference voltage input from the negative reference voltage interface 13 is selected to be connected in parallel with the input signal input from the input signal interface 11 for summation in the selection summing unit 101, and the summation result is output to the latch amplifier 102 through the summation result interface 17.

The selection summing unit 101 is configured to selectively select the positive reference voltage input from the positive reference voltage interface 12 or the negative reference voltage input from the negative reference voltage interface 13 to sum with the input signal input from the input signal interface 11 to obtain a summation result when the sampling clock 15 is at a high level.

In some embodiments, a drain of the first NMOS transistor M1, a drain of the second NMOS transistor M2 and a drain of the third NMOS transistor M3 are connected to one another and to the summation result interface 17. A source of the first NMOS transistor M1, a source of the fourth NMOS transistor M4 and a source of the fifth NMOS transistor M5 are connected to one another and to the summation source interface. A source of the second NMOS transistor M2 is connected to a drain of the fourth NMOS transistor M4; a source of the third NMOS transistor M3 is connected to a drain of the fifth NMOS transistor M5.

In some embodiments, a drain of the first NMOS transistor M1, a drain of the fourth NMOS transistor M4 and a drain of the fifth NMOS transistor M5 are connected to one another and to the summation result interface 17. A source of the first NMOS transistor M1, a source of the second NMOS transistor M2 and a source of the third NMOS transistor M3 are connected to one another and to the summation source interface 16. A drain of the second NMOS transistor M2 is connected to a source of the fourth NMOS transistor M4; a drain of the third NMOS transistor M3 is connected to a source of the fifth NMOS transistor M5.

According to an embodiment of the present invention, the sampler 103 is connected to the selection summing unit 101 through the summation source interface 16, and the sampling clock 15 is connected to the sampler 103.

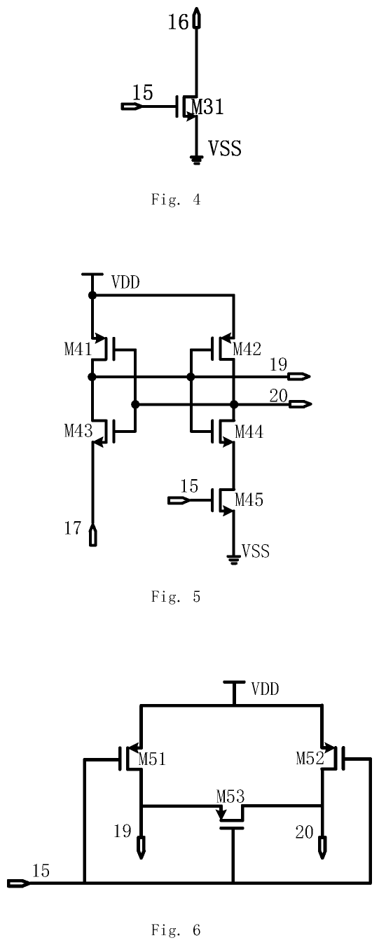

As shown in FIG. 4, the sampler 103 comprises one or more first sampling MOS transistors M31, and a gate of each first sampling MOS transistor M31 is connected to the sampling clock 15.

When the sampling clock 15 is at a high level, the first sampling MOS transistor M31 samples the selection summing unit 101 through the summation source interface.

In some embodiments, a drain of the first sampling MOS transistor M31 is connected to the summation source interface 16, and a source of the first sampling MOS transistor M31 is connected to the ground terminal VSS.

In some embodiments, a source of the first sampling MOS transistor M31 is connected to the summation source interface 16, and a drain of the first sampling MOS transistor M31 is connected to the ground terminal VSS.

According to an embodiment of the present invention, the latch amplifier 102 is connected to the selection summing unit 101 through the summation result interface 17, and the sampling clock 15 is connected to the latch amplifier 102.

As shown in FIG. 5, the latch amplifier 102 comprises a first latch MOS transistor M41, a second latch MOS transistor M42, a third latch MOS transistor M43, a fourth latch MOS transistor M44 and a second sampling MOS transistor M45.

The first latch MOS transistor M41 and the third latch MOS transistor M43 are connected in series to form a first latch branch, and the second sampling MOS transistor M45, the second latch MOS transistor M42 and the fourth latch MOS transistor M44 are connected in series to form a second latch branch. The first latch branch and the second latch branch are connected in parallel, a gate of the second sampling MOS transistor M45 is connected to the sampling clock 15, and the third latch MOS transistor M43 is connected to the summation result interface 17.

The first latch branch (the first latch MOS transistor M41 and the third latch MOS transistor M43) is connected to the positive output signal terminal 19 and the negative output signal terminal 20.

The second latch branch (the second latch MOS transistor M42 and the fourth latch MOS transistor M44) is connected to the positive output signal terminal 19 and the negative output signal terminal 20.

When the sampling clock 15 is at a high level, the second sampling MOS transistor M45 is turned on, the first latch MOS transistor M41, the second latch MOS transistor M42, the third latch MOS transistor M43 and the fourth latch MOS transistor M44 form a positive feedback loop, latch and amplify the summation result through the summation result interface 17, and output the output result to the positive output signal terminal 19 and the negative output signal terminal 20.

When the sampling clock 15 is at a low level, the second sampling MOS transistor M45, the second latch MOS transistor M42 and the fourth latch MOS transistor M44 are all turned off, and the positive output signal terminal 19 and the negative output signal terminal 20 are not controlled by the latch amplifier 102.

In some embodiments, a source of the second sampling MOS transistor M45 is connected to the ground terminal VSS; a drain of the second sampling MOS transistor M45 is connected to a source of the fourth latch MOS transistor M44; a drain of the fourth latch MOS transistor M44 is connected to a drain of the second latch MOS transistor M42.

A source of the third latch MOS transistor M43 is connected to the summation result interface 17; a drain of the third latch MOS transistor M43 is connected to a drain of the first latch MOS transistor M41.

A source of the second latch MOS transistor M42 and a source of the first latch MOS transistor M41 are connected to the power supply VDD.

In some embodiments, a drain of the second sampling MOS transistor M45 is connected to the ground terminal VSS; a source of the second sampling MOS transistor M45 is connected to a drain of the fourth latch MOS transistor M44; a source of the fourth latch MOS transistor M44 is connected to a source of the second latch MOS transistor M42.

A drain of the third latch MOS transistor M43 is connected to the summation result interface 17; a source of the third latch MOS transistor M43 is connected to a source of the first latch MOS transistor M41;

A drain of the second latch MOS transistor M42 and a drain of the first latch MOS transistor M41 are connected to the power supply VDD.

According to an embodiment of the present invention, the positive output signal terminal 19 and the negative output signal terminal 20 of the latch amplifier 102 are connected to the resetter 104, and the sampling clock 15 is connected to the resetter 104.

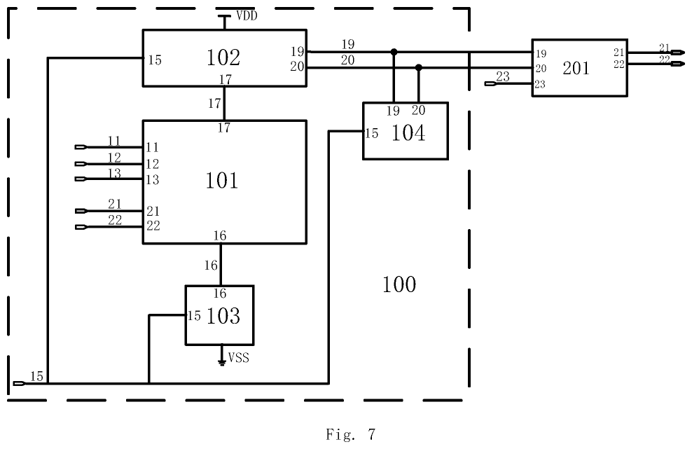

As shown in FIG. 6, the resetter 104 comprises a first reset MOS transistor M51, a second reset MOS transistor M52 and a third reset MOS transistor M53.

A gate of the first reset MOS transistor M51, a gate of the second reset MOS transistor M52 and a gate of the third reset MOS transistor M53 are connected to the sampling clock 15 respectively.

The first reset MOS transistor M51 and the second reset MOS transistor M52 are connected in parallel, the positive output signal terminal 19 of the latch amplifier 102 is connected to the first reset MOS transistor M51, the negative output signal terminal 20 of the latch amplifier 102 is connected to the second reset MOS transistor M52, and the first reset MOS transistor M51 and the second reset MOS transistor M52 are both connected to the power supply VDD. The third reset MOS transistor M53 is connected between the positive output signal terminal 19 and the negative output signal terminal 20 of the latch amplifier 102.

When the sampling clock 15 is at a low level, the first reset MOS transistor M51, the second reset MOS transistor M52 and the third reset MOS transistor M53 are all turned on, the positive output signal terminal 19 and the negative output signal terminal 20 of the latch amplifier 102 are connected to the power supply VDD through the first reset MOS transistor M51 and the second reset MOS transistor M52, and the third reset MOS transistor M53 turns on the first reset MOS transistor M51 and the second reset MOS transistor M52 at the same time to reset the positive output signal terminal 19 and the negative output signal terminal 20 of the latch amplifier 102.

When the sampling clock 15 is at a high level, the first reset MOS transistor M51, the second reset MOS transistor M52 and the third reset MOS transistor M53 are all turned off, without affecting the operation of other circuits.

In some embodiments, a drain of the first reset MOS transistor M51 is connected to the positive output signal terminal 19, and a source of the third reset MOS transistor M53 is connected to the positive output signal terminal 19.

A drain of the second reset MOS transistor M52 is connected to the negative output signal terminal 20, and a drain of the third reset MOS transistor M53 is connected to the negative output signal terminal 20.

A source of the first reset MOS transistor M51 and a source of the second reset MOS transistor M52 are connected to the power supply VDD.

In some embodiments, a source of the first reset MOS transistor M51 is connected to the positive output signal terminal 19, and a drain of the third reset MOS transistor M53 is connected to the positive output signal terminal 19.

A source of the second reset MOS transistor M52 is connected to the negative output signal terminal 20, and a source of the third reset MOS transistor M53 is connected to the negative output signal terminal 20.

A drain of the first reset MOS transistor M51 and a drain of the second reset MOS transistor M52 are connected to the power supply VDD.

As shown in FIG. 7, according to an embodiment of the present invention, a decision feedback equalizer is provided, which comprises a latch 201 and the selection summing latch circuit 100 provided by the present invention. The selection summing latch circuit 100 is the selection summing latch circuit 100 provided in the above embodiments of the present invention, and will not be repeated here.

The latch 201 is provided with a latch clock 23, and the latch clock 23 and the sampling clock 15 are inverse phase signals to each other. The positive output signal terminal 19 and the negative output signal terminal 20 of the selection summing latch circuit 100 are connected to the latch 201, and an output end of the latch 201 is connected to the positive selection signal terminal 21 and the negative selection signal terminal 22 of the selection summing latch circuit 100, forming a closed-loop decision feedback equalizer. The summation function, selection function, sampling function and latching function used in the decision feedback equalizer are integrated into the selection summing latch circuit, thereby reducing the overall power consumption, lowering the overall time delay and improving the circuit performance.

Although the embodiments of the present invention have been shown and described above, it should be understood that the above embodiments are exemplary and should not be construed as limiting the present invention, and changes, modifications, substitutions and variations made to the above embodiments by those skilled in the art within the scope of the present invention shall all fall within the protection scope of the present invention.

What is claimed is:

1. A selection summing latch circuit for a decision feedback equalizer, characterized in that the selection summing latch circuit comprises a selection summing unit, a latch amplifier, a sampler and a resetter;
the selection summing unit is configured to selectively select a positive reference voltage or a negative reference voltage to sum with an input signal according to the logic levels of a positive selection signal terminal and a negative selection signal terminal to obtain a summation result when a sampling clock is at a high level;
the latch amplifier is configured to latch and amplify the summation result and output an output result to a positive output signal terminal and a negative output signal terminal when the sampling clock is at a high level;
the sampler is configured to sample the selection summing unit when the sampling clock is at a high level;
the resetter is configured to reset the positive output signal terminal and the negative output signal terminal when the sampling clock is at a low level.

2. The selection summing latch circuit according to claim 1, characterized in that the selection summing unit comprises a first NMOS transistor, a second NMOS transistor, a third NMOS transistor, a fourth NMOS transistor and a fifth NMOS transistor;
wherein the second NMOS transistor and the fourth NMOS transistor are connected in series to form a first branch, and the third NMOS transistor and the fifth NMOS transistor are connected in series to form a second branch;
the first NMOS transistor is connected in parallel with the first branch and the second branch respectively.

3. The selection summing latch circuit according to claim 2, characterized in that a gate of the first NMOS transistor is connected to an input signal interface; a gate of the second NMOS transistor is connected to a positive reference voltage interface; a gate of the third NMOS transistor is connected to a negative reference voltage interface; a gate of the fourth NMOS transistor is connected to the positive selection signal terminal; a gate of the fifth NMOS transistor is connected to the negative selection signal terminal;
wherein the logic levels of the positive selection signal terminal and the negative selection signal terminal are opposite.

4. The selection summing latch circuit according to claim 2, characterized in that a drain of the first NMOS transistor, a drain of the second NMOS transistor and a drain of the third NMOS transistor are connected to one another and to a summation result interface;
a source of the first NMOS transistor, a source of the fourth NMOS transistor and a source of the fifth NMOS transistor are connected to one another and to a summation source interface;
a source of the second NMOS transistor is connected to a drain of the fourth NMOS transistor; a source of the third NMOS transistor is connected to a drain of the fifth NMOS transistor.

5. The selection summing latch circuit according to claim 2, characterized in that a drain of the first NMOS transistor, a drain of the fourth NMOS transistor and a drain of the fifth NMOS transistor are connected to one another and to a summation result interface;
a source of the first NMOS transistor, a source of the second NMOS transistor and a source of the third NMOS transistor are connected to one another and to a summation source interface;
a drain of the second NMOS transistor is connected to a source of the fourth NMOS transistor; a drain of the third NMOS transistor is connected to a source of the fifth NMOS transistor.

6. The selection summing latch circuit according to claim 1, characterized in that the sampler is connected to the selection summing unit through the summation source interface;
the sampler comprises one or more first sampling MOS transistors, and a gate of each first sampling MOS transistor is connected to the sampling clock;
when the sampling clock is at a high level, the first sampling MOS transistor samples the selection summing unit through the summation source interface.

7. The selection summing latch circuit according to claim 6, characterized in that a drain of the first sampling MOS transistor is connected to the summation source interface, and a source of the first sampling MOS transistor is connected to a ground terminal VSS.

8. The selection summing latch circuit according to claim 6, characterized in that a source of the first sampling MOS transistor is connected to the summation source interface, and a drain of the first sampling MOS transistor is connected to the ground terminal VSS.

9. The selection summing latch circuit according to claim 1, characterized in that the latch amplifier is connected to the selection summing unit through the summation result interface;
the latch amplifier comprises a first latch MOS transistor, a second latch MOS transistor, a third latch MOS transistor, a fourth latch MOS transistor and a second sampling MOS transistor;
the first latch MOS transistor and the third latch MOS transistor are connected in series to form a first latch branch, and the second sampling MOS transistor, the second latch MOS transistor and the fourth latch MOS transistor are connected in series to form a second latch branch;
the first latch branch and the second latch branch are connected in parallel, a gate of the second sampling MOS transistor is connected to the sampling clock, and the third latch MOS transistor is connected to the summation result interface;
the first latch branch is connected to the positive output signal terminal and the negative output signal terminal;
the second latch branch is connected to the positive output signal terminal and the negative output signal terminal.

10. The selection summing latch circuit according to claim 9, characterized in that when the sampling clock is at a high level, the second sampling MOS transistor is turned on, the first latch MOS transistor, the second latch MOS transistor, the third latch MOS transistor and the fourth latch MOS transistor form a positive feedback loop, latch and amplify the summation result through the summation result interface, and output the output result to the positive output signal terminal and the negative output signal terminal;
when the sampling clock is at a low level, the second sampling MOS transistor, the second latch MOS transistor and the fourth latch MOS transistor are all turned off.

11. The selection summing latch circuit according to claim 9, characterized in that a source of the second sampling MOS transistor is connected to the ground terminal VSS; a drain of the second sampling MOS transistor is connected to a source of the fourth latch MOS transistor; a drain of the fourth latch MOS transistor is connected to a drain of the second latch MOS transistor;
a source of the third latch MOS transistor is connected to the summation result interface; a drain of the third latch MOS transistor is connected to a drain of the first latch MOS transistor;
a source of the second latch MOS transistor and a source of the first latch MOS transistor are connected to a power supply VDD.

12. The selection summing latch circuit according to claim 9, characterized in that a drain of the second sampling MOS transistor is connected to the ground terminal VSS; a source of the second sampling MOS transistor is connected to a drain of the fourth latch MOS transistor; a source of the fourth latch MOS transistor is connected to a source of the second latch MOS transistor;
a drain of the third latch MOS transistor is connected to the summation result interface; a source of the third latch MOS transistor is connected to a source of the first latch MOS transistor;
a drain of the second latch MOS transistor and a drain of the first latch MOS transistor are connected to the power supply VDD.

13. The selection summing latch circuit according to claim 1, characterized in that the resetter comprises a first reset MOS transistor, a second reset MOS transistor and a third reset MOS transistor;
a gate of the first reset MOS transistor, a gate of the second reset MOS transistor and a gate of the third reset MOS transistor are connected to the sampling clock respectively;
the first reset MOS transistor and the second reset MOS transistor are connected in parallel, the positive output signal terminal is connected to the first reset MOS transistor, the negative output signal terminal is connected to the second reset MOS transistor, and the first reset MOS transistor and the second reset MOS transistor are both connected to a power supply VDD;
the third reset MOS transistor is connected between the positive output signal terminal and the negative output signal terminal.

14. The selection summing latch circuit according to claim 13, characterized in that when the sampling clock is at a low level, the first reset MOS transistor, the second reset MOS transistor and the third reset MOS transistor are all turned on to reset the positive output signal terminal and the negative output signal terminal;
when the sampling clock is at a high level, the first reset MOS transistor, the second reset MOS transistor and the third reset MOS transistor are all turned off.

15. The selection summing latch circuit according to claim 13, characterized in that a drain of the first reset MOS transistor is connected to the positive output signal terminal, and a source of the third reset MOS transistor is connected to the positive output signal terminal;
a drain of the second reset MOS transistor is connected to the negative output signal terminal, and a drain of the third reset MOS transistor is connected to the negative output signal terminal;
a source of the first reset MOS transistor and a source of the second reset MOS transistor are connected to the power supply VDD.

16. The selection summing latch circuit according to claim 13, characterized in that a source of the first reset MOS transistor is connected to the positive output signal terminal, and a drain of the third reset MOS transistor is connected to the positive output signal terminal;
a source of the second reset MOS transistor is connected to the negative output signal terminal, and a source of the third reset MOS transistor is connected to the negative output signal terminal;
a drain of the first reset MOS transistor and a drain of the second reset MOS transistor are connected to the power supply VDD.

17. A decision feedback equalizer, characterized in that the decision feedback equalizer comprises a latch and the selection summing latch circuit according to claim 1.

18. The decision feedback equalizer according to claim 17, characterized in that the positive output signal terminal and the negative output signal terminal of the selection summing latch circuit are connected to the latch;
an output end of the latch is connected to the positive selection signal terminal and the negative selection signal terminal of the selection summing latch circuit;
the latch is provided with a latch clock, and the latch clock and the sampling clock are inverse phase signals to each other.
